(19) United States
(12) Patent Application Publication
(10) Pub. No.: US 2008/0216884 A1
(43) Pub. Date: Sep. 11, 2008

(54) Clathrate Compounds, Thermoelectric Conversion Elements, and Methods For Producing the Same

(76) Inventors: Yasufumi Shibata, Shizuoka (JP); Hiroaki Anno, Yamaguchi (JP); Kakuei Matsubara, Yamaguchi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/587,718

(22) PCT Filed: Jan. 24, 2005
(86) PCT No.: PCT/JP05/01284

§ 371 Date: Jun. 7, 2007

(30) Foreign Application Priority Data
Jan. 30, 2004 (JP) 2004-024310

(51) Int. Cl. H01L 35/14; C22C 28/00

(52) U.S. Cl. 136/239; 420/556

(57) ABSTRACT

BaAuGe, BaAuGaGe, BaPtGe, BaPdGe, BaPdGaGe, BaPdGaSi, BaPtGaSi, BaCuGaGe, and BaAgGaGe clathrate compounds, and thermoelectric conversion element comprising the clathrate compounds. Methods for producing thermoelectric conversion elements are also provided, comprising melting, heat-treating, particle-forming, and sintering processes.

### CROSS-REFERENCE TO RELATED APPLICATION

This application claims priority under 35 USC 119 from Japanese patent Application No. 2004-024310, the disclosure of which is incorporated by reference herein.

### FIELD OF THE INVENTION

The invention is related to clathrate compounds, thermoelectric conversion elements, and production methods thereof.

### DESCRIPTION OF THE RELATED ART

Thermoelectric conversion elements utilizing the Seebeck effect realizes conversion of thermal energy to electric energy. Thermoelectric conversion elements can convert the heat discharged from industrial and consumer processes or from vehicles to effective electric power through the effect. Therefore, the elements have been considered as an environment-friendly energy saving technology and have attracted attention.

The thermoelectric figure of merit can be represented by ZT. The thermoelectric figure of merit of a thermoelectric material used in a thermoelectric conversion element utilizing the Seebeck effect can be represented by the following formula (A):

ZT=α²σT/κ Formula (A)

In the formula (A), α represents the Seebeck coefficient, σ represents the electric conductivity, κ represents the thermal conductivity, and T represents the temperature at the measurement.

As is clear from the formula (A), the performance of a thermoelectric conversion element can be improved by increasing the Seebeck coefficient or electric conductivity of the material used in the element or by decreasing the thermal conductivity thereof.

Z in ZT is proportional to a function of the effective mass (m*), the mobility (μ), and the thermal conductivity (κ), the function being represented by the following formula (B):

Z∝m*^{3/2}μ/κ Formula (B)

The formula (B) indicates that Z can be increased by increasing the effective mass or the mobility.

Some thermoelectric materials have been known to have high thermoelectric figures of merit such as bismuth-tellurium materials, silicon-germanium materials, and lead-tellurium material. In addition, a thermoelectric material prepared by molding and sintering zinc oxide powder doped with aluminum has been known (See Japanese Patent Application Laid-Open (JP-A) No. 2002-118296, the disclosure of which is incorporated by reference herein).

### SUMMARY OF THE INVENTION

An object of the invention is to provide novel clathrate compounds which can preferably used in thermoelectric conversion elements. Another object of the invention is to provide thermoelectric conversion elements having excellent thermoelectric characteristics and methods for producing the thermoelectric conversion elements.

A first aspect of the invention is to provide a clathrate compound represented by the following composition formula (1):

Ba₈AuₐGe₄₆₋ₐ(16/3≦a≦6). Composition formula (1)

A second aspect of the invention is to provide a clathrate compound represented by the following composition formula (2):

Ba₈Au_{b}Ga_{c}Ge_{46-b-c}(5≦b<16/3,c=16−3b). Composition formula (2)

A third aspect of the invention is to provide a clathrate compound represented by the following composition formula (3):

Ba₈Au_{d}GaₑGe_{46-d-e}(0≦d<5,e=16−3d). Composition formula (3)

A fourth aspect of the invention is to provide a clathrate compound represented by the following composition formula (4):

Ba₈Au_{f}Ga_{6-f}Ge₄₀(0<f<6). Composition formula (4)

A fifth aspect of the invention is to provide the clathrate compound represented by the following composition formula (5):

Ba₈Pt_{g}Ge_{46-g}(4<g<6). Composition formula (5)

A sixth aspect of the invention is to provide a clathrate compound represented by the following composition formula (6):

Ba₈PdₕGe₄₆₋ₕ(5<h<6). Composition formula (6)

A seventh aspect of the invention is to provide a clathrate compound represented by the following composition formula (7):

Ba₈PdᵢGaⱼGe₄₆₋ᵢ₋ⱼ(0≦i≦4,j=16−4i). Composition formula (7)

An eighth aspect of the invention is to provide a clathrate compound represented by the following composition formula (8):

Ba₈AₖGa₁Si₄₆₋ₖ₋₁(0≦k≦4,l=16−4k) Composition formula (8)

wherein A in Composition formula (8) represents Pd or Pt.

A ninth aspect of the invention is to provide a clathrate compound represented by the following composition formula (9):

Ba₈EₘGa₆₋ₘGe₄₀(5<m<6) Composition formula (9)

wherein E in Composition formula (9) represents Cu or Ag.

A tenth aspect of the invention is to provide a clathrate compound represented by the following composition formula (10):

Ba₈GₙGa₆₋ₙGe₄₀(0<n≦5) Composition formula (10)

wherein G in Composition formula (10) represents Cu or Ag.

An eleventh aspect of the invention is to provide a clathrate compound represented by the following composition formula (11):

Ba₈J₀GaₚGe₄₆₋ₒ₋ₚ(0≦o≦16/3,p=16−3o) Composition formula (11)

wherein J in Composition formula (11) represents Cu or Ag.

A twelfth aspect of the invention is to provide a thermoelectric conversion element comprising a sintered body of the clathrate compound represented by the following composition formula (1):

Ba₈AuₐGe₄₆₋ₐ(16/3≦a≦6). Composition formula (1)

A thirteenth aspect of the invention is to provide a thermoelectric conversion element comprising a sintered body of the clathrate compound represented by the following composition formula (2):

Ba₈Au_{b}Ga_{c}Ge_{46-b-c}(5≦b<16/3,c=16−3b). Composition formula (2)

A fourteenth aspect of the invention is to provide a thermoelectric conversion element comprising a sintered body of the clathrate compound represented by the following composition formula (3):

Ba₈Au_{d}GaₑGe_{46-d-e}(0≦d<5,e=16−3d). Composition formula (3)

A fifteenth aspect of the invention is to provide a thermoelectric conversion element comprising a sintered body of the clathrate compound represented by the following composition formula (4):

Ba₈Au_{f}Ga_{6-f}Ge₄₀(0<f<6). Composition formula (4)

A sixteenth aspect of the invention is to provide a thermoelectric conversion element comprising a sintered body of the clathrate compound represented by the following composition formula (5):

Ba₈Pt_{g}Ge_{46-g}(4<g<6). Composition formula (5)

A seventeenth aspect of the invention is to provide a thermoelectric conversion element comprising a sintered body of the clathrate compound represented by the following composition formula (6):

Ba₈PdₕGe₄₆₋ₕ(5<h<6). Composition formula (6)

An eighteenth aspect of the invention is to provide a thermoelectric conversion element comprising a sintered body of the clathrate compound represented by the following composition formula (7):

Ba₈PdᵢGaⱼGe₄₆₋ᵢ₋ⱼ(0≦i≦4,j=16−4i). Composition formula (7)

A nineteenth aspect of the invention is to provide a thermoelectric conversion element comprising a sintered body of the clathrate compound represented by the following composition formula (8):

Ba₈AₖGa₁Si₄₆₋ₖ₋₁(0≦k≦4,l=16−4k) Composition formula (8)

wherein A in Composition formula (8) represents Pd or Pt.

A twentieth aspect of the invention is to provide a thermoelectric conversion element comprising a sintered body of the clathrate compound represented by the following composition formula (9):

Ba₈EₘGa₆₋ₘGe₄₀(5<m<6) Composition formula (9)

wherein E in Composition formula (9) represents Cu or Ag. A twenty-first aspect of the invention is to provide a thermoelectric conversion element comprising a sintered body of the clathrate compound represented by the following composition formula (10):

Ba₈GₙGa₆₋ₙGe₄₀(0<n≦5) Composition formula (10)

wherein G in Composition formula (10) represents Cu or Ag.

A twenty-second aspect of the invention is to provide a thermoelectric conversion element comprising a sintered body of the clathrate compound represented by the following composition formula (11):

Ba₈J₀GaₚGe₄₆₋ₒ₋ₚ(0≦o≦16/3,p=16−3o) Composition formula (11)

wherein J in Composition formula (11) represents Cu or Ag.

A twenty-third aspect of the invention is to provide a method for producing a thermoelectric conversion element comprising a sintered body of a clathrate compound whose constituent atoms include Ba and Ge, the method comprising:

melting elements which are to constitute the clathrate compound so as to synthesize the clathrate compound;

heat-treating the synthesized clathrate compound at 650 to 900° C. for 50 to 250 hours;

forming particles from the heat-treated clathrate compound; and

sintering the particles.

### BRIEF DESCRIPTION OF THE DRAWINGS

FIG. 1 is a figure showing the Seebeck coefficients of the thermoelectric conversion element 1.

FIG. 2 is a figure showing the data obtained by X-ray crystal structure analysis of the thermoelectric conversion elements 2, 12, 13, and 16.

FIG. 3 is a figure showing the Seebeck coefficients of the thermoelectric conversion elements 2, 7, 8, 9, 12, and 13.

FIG. 4 is a figure showing the electric conductivity values of the thermoelectric conversion elements 2, 7, 8, 9, 12, and 13.

FIG. 5 is a figure showing the power factors of the thermoelectric conversion elements 2, 7, 8, 9, 12, and 13.

FIG. 6 is a figure showing the power factors of the thermoelectric conversion elements 3 and 4.

FIG. 7 is a figure showing the Seebeck coefficients of the thermoelectric conversion elements 5 and 6.

FIG. 8 is a figure showing the Seebeck coefficients of the thermoelectric conversion elements 10 and 11.

FIG. 9 is a figure showing the power factors of the thermoelectric conversion elements 14 and 15.

FIG. 10 is a figure showing the relationships between the hole mobility and the carrier concentration of the thermoelectric conversion elements 16 and 17.

FIG. 11 is a figure showing the electric conductivity values of the thermoelectric conversion elements 16, 17, 18, and 19.

### DESCRIPTION OF THE PRESENT INVENTION

In the following, the clathrate compounds, thermoelectric conversion elements, and production methods thereof of the invention is described in detail.

The clathrate compound 1 of the invention is represented by the following composition formula (1):

Ba₈AuₐGe₄₆₋ₐ(16/3≦a≦6). Composition formula (1)

The clathrate compound 1 of the invention includes trivalent Au as an acceptor. The clathrate compound 1 shows p-type semiconductor characteristics (in other words, the Seebeck coefficient is a positive value). When “a” in the composition formula (1) is out of the specified range, the resultant clathrate compound does not have p-type semiconductor characteristics.

The clathrate compound 2 of the invention is represented by the following composition formula (2):

Ba₈Au_{b}Ga_{c}Ge_{46-b-c}(5≦b<16/3,c=16−3b). Composition formula (2)

The clathrate compound 2 includes trivalent Au as an acceptor. The clathrate compound 2 has p-type semiconductor characteristics (in other words, the Seebeck coefficient is a positive value). When b in the composition formula (2) is out of the specified range, the resultant clathrate compound does not have p-type semiconductor characteristics.

The clathrate compound 3 of the invention is represented by the following composition formula (3):

Ba₈Au_{d}GaₑGe_{46-d-e}(0≦d<5,e=16−3d). Composition formula (3)

The clathrate compound 3 includes trivalent Au as an acceptor. The clathrate compound 3 belongs to BaAuGaGe clathrate compounds and shows thermoelectric characteristics.

In the clathrate compound 3, d preferably satisfies 3<d<5, and more preferably, 3.5<d<5.

The clathrate compound 4 of the invention is represented by the following composition formula (4):

Ba₈Au_{f}Ga_{6-f}Ge₄₀(0<f<6). Composition formula (4)

The clathrate compound 4 includes trivalent Au as an acceptor. The clathrate compound 4 belongs to BaAuGaGe clathrate compounds and shows thermoelectric characteristics. When f=0, the effect of the addition of Au cannot be obtained. When f is 6 or more, the resultant clathrate compound does not have thermoelectric characteristics.

In the clathrate compound 4, f preferably satisfies 3.5<f<6, and more preferably, 3.8<f<5.5.

The clathrate compound 5 of the invention is represented by the following composition formula (5):

Ba₈Pt_{g}Ge_{46-g}(4<g<6). Composition formula (5)

The clathrate compound 5 includes tetravalent Pt as an acceptor. The clathrate compound 5 shows p-type semiconductor characteristics (in other words, the Seebeck coefficient is a positive value). When g in the composition formula (5) is out of the specified range, the resultant clathrate compound does not have p-type semiconductor characteristics.

g preferably satisfies 4.5<g<5.5.

The clathrate compound 6 of the invention is represented by the following composition formula (6):

Ba₈PdₕGe₄₆₋ₕ(5<h<6). Composition formula (6)

The clathrate compound 6 includes tetravalent Pd as an acceptor. The clathrate compound 6 shows p-type semiconductor characteristics (in other words, the Seebeck coefficient is a positive value). When h in the composition formula (6) is out of the specified range, the resultant clathrate compound does not have p-type semiconductor characteristics.

The clathrate compound 7 of the invention is represented by the following composition formula (7):

Ba₈PdᵢGaⱼGe₄₆₋ᵢ₋ⱼ(0≦i≦4,j=16−4i). Composition formula (7)

The clathrate compound 7 includes tetravalent Pd as an acceptor. The clathrate compound 7 belongs to BaPdGaGe clathrate compounds and shows thermoelectric characteristics. Further, the clathrate compound 7 shows an increased power factor (α²σ) at 700 K or lower when compared with BaGaGe clathrate compounds. When i in the composition formula (7) is out of the specified range, the resultant clathrate compound does not have thermoelectric characteristics.

In the clathrate compound 7, i preferably satisfies 1<i<4, more preferably, 1<i<3.

The clathrate compound 8 of the invention is represented by the following composition formula (8):

Ba₈AₖGa₁Si₄₆₋ₖ₋₁(0≦k≦4,l=16−4k) Composition formula (8)

In the composition formula (8), A represents Pd or Pt.

The clathrate compound 8 includes tetravalent Pd or Pt as an acceptor. The clathrate compound 8 belongs to BaAGaSi (A represents Pd or Pt) clathrate compounds and shows thermoelectric characteristics. The clathrate compound 8 shows a nearly constant electric conductivity (about 1000 s/cm) within the temperature range of ambient temperature to 900° C. When k in the composition formula (8) is out of the specified range, the resultant clathrate compound does not have thermoelectric characteristics.

In the clathrate compound 8, k preferably satisfies 1<k<4, more preferably, 1<k<3.

The clathrate compound 9 of the invention is represented by the following composition formula (9):

Ba₈EₘGa₆₋ₘGe₄₀(5<m<6) Composition formula (9)

In the composition formula (9), E represents Cu or Ag.

The clathrate compound 9 includes trivalent Cu or Ag as an acceptor. The clathrate compound 9 shows p-type semiconductor characteristics (in other words, the Seebeck coefficient is a positive value). When m in the composition formula (9) is out of the specified range, the resultant clathrate compound does not have p-type semiconductor characteristics.

The clathrate compound 10 of the invention is represented by the following composition formula (10):

Ba₈GₙGa₆₋ₙGe₄₀(0<n≦5) Composition formula (10)

In the composition formula 10, G represents Cu or Ag.

The clathrate compound 10 includes trivalent Cu or Ag as an acceptor. The clathrate compound 10 belongs to Cu-based or Ag-based clathrate compounds and shows thermoelectric characteristics. If n in the composition formula (10) is 0, the effect of the addition of Cu or Ag cannot be obtained. If n is larger than 5, the resultant clathrate compound does not have thermoelectric characteristics.

In the clathrate compound 10, n preferably satisfies 4.5<n≦5, more preferably, 4.8<n≦5.

The clathrate compound 11 of the invention is represented by the following composition formula (11):

Ba₈J₀GaₚGe₄₆₋ₒ₋ₚ(0<o<16/3,p=16−3o) Composition formula (11)

In the composition formula (11), J represents Cu or Ag.

The clathrate compound 11 includes trivalent Cu or Ag as an acceptor. The clathrate compound 11 belongs to Cu-based or Ag-based clathrate compounds and shows thermoelectric characteristics. If n in the composition formula (11) is 0, the effect of the addition of Cu or Ag cannot be obtained. If n is larger than 16/3, the resultant clathrate compound does not have thermoelectric characteristics.

In the clathrate compound 11, o preferably satisfies 3<o<5, more preferably, 3.5<o<4.5.

The clathrate compound of the invention can be synthesized, for example through a process comprising melting the elements which are to constitute the clathrate compound. The melting temperature is preferably 1000 to 1500° C., more preferably 1000 to 1400° C., particularly preferably, 1200 to 1400° C. The melting time is preferably 10 to 100 minutes, more preferably, 10 to 60 minutes, particularly preferably, 20 to 60 minutes. The melting method may be, for example, the arc melting method or high-frequency heating method.

The thermoelectric conversion element of the invention comprises a sintered body of the clathrate compound of the invention. The thermoelectric conversion element of the invention may be produced, for example by a process comprising: atomizing the clathrate compound of the invention; and sintering the particles of the clathrate compound.

In the process, the clathrate compound can be atomized by being pulverized with a ball mill or a mortar. The particle size of the clathrate particles is preferably no larger than 150 μm, more preferably, no larger than 90 μm. The flowing gas evaporation method can also be used in which vapor of the clathrate compound is generated in vacuum then blown by a high-pressure inert gas. The details of the flowing gas evaporation method is described in Japanese Patent Publication (JP-B) No. 5-9483, the disclosure of which is incorporated by reference herein. In the process, the particles can be sintered by, for example, the discharge plasma sintering method, the hot-press method, or the hot isostatic pressing sintering method.

In the discharge plasma sintering method, the sintering temperature is preferably 650 to 950° C., more preferably, 700 to 900° C. The sintering time is preferably 20 to 120 minutes, more preferably, 30 to 90 minutes. The pressure is preferably 25 to 40 MPa, more preferably, 30 to 40 MPa.

Among the thermoelectric conversion elements of the invention, the elements comprising a sintered body of the clathrate compound whose constituent atoms include Ba and Ge can be produced by a method of the invention comprising: melting the elements which are to constitute the clathrate compound, so as to synthesize the clathrate compound; heat-treating the synthesized clathrate compound at 650 to 900° C. for 50 to 250 hours; atomizing the heat-treated clathrate compound; and sintering the particles of the clathrate compound.

According to the method of the invention for producing thermoelectric conversion elements, the mobility of the thermoelectric conversion element can be improved. Therefore, the electric conductivity of the thermoelectric conversion element can be improved. The mechanism is considered as follows: unreacted constituent atoms in the clathrate compound synthesized in the melting process are allowed to react when heat-treated to form a clathrate compound, and defects in the crystal structure of the clathrate compound disappear.

If the heating temperature at the heat-treatment is below 650° C., unreacted constituent atoms are unlikely to react sufficiently; therefore, the mobility of the thermoelectric conversion element is unlikely to increase. If the heating temperature is higher than 900° C., unreacted constituent atoms is likely to evaporate or be oxidized so that the composition is likely to change.

If the heating time is shorter than 50 hours, unreacted constituent atoms are likely to react only insufficiently and to fail to raise the mobility. If the heating time is longer than 250 hours, the clathrate compound is likely to be oxidized and the electric conductivity of the clathrate compound is likely to decrease.

The heating temperature at the heat-treatment is preferably 700 to 800° C. The heating time is preferably 100 to 200 hours.

In an embodiment, the clathrate compound synthesized in the melting process is cooled, then subjected to the heat-treatment. In another embodiment, after the synthesis of the clathrate compound in the melting process, the processing temperature is changed from the melting temperature to the heat-treatment temperature so that the clathrate compound is subjected to the heat-treatment. Preferably, the clathrate compound is subjected to the heat-treatment after being cooled.

The method of the invention for producing the thermoelectric conversion element is applicable to the production of thermoelectric conversion elements comprising Ba and Ge as constituent atoms. The method of the invention can be applied to, for example, quaternary clathrate compounds such as the clathrate compounds 3, 4, 7, 9, 10, and 11 of the invention and to ternary clathrate compounds comprising Ba, Ga, and Ge as the constituent atoms.

The formation of the clathrate compound of the invention can be confirmed by X-ray diffraction. Specifically, if a sintered sample is found to comprise only the clathrate phase by an X-ray diffraction, it is confirmed that the clathrate compound was synthesized.

### EXAMPLES

The invention will be described in more detail with reference to examples. However, the examples are given to illustrate the invention and not to be construed to limit the scope of the invention.

### Example 1

### Preparation of Thermoelectric Conversion Element 1 (Ba₈Au_{5.5}Ge_{40.5})

Ba (99.9%), Au (99.9%), and Ge (99.9%) were used as raw materials. 4.9335 g of Ba, 4.8634 g of Au, and 13.1883 g of Ge were mixed so that the molar ratio of Ba:Au:Ge was 8:5.5:40.5. Therefore, the total weight was about 23 g. The mixture was melted by being subjected to an arc melting wherein the arc temperature was 1200° C. and the arc melting time was 20 minutes. Thereafter, the mixture was cooled so that Ba₈Au_{5.5}Ge_{40.5} was synthesized. Then, the synthesized substance Ba₈Au_{5.5}Ge_{40.5} was pulverized with a mortar into particles having a particle size of 75 μm or smaller. The particles of Ba₈Au_{5.5}Ge_{40.5} were sintered by a discharge plasma sintering device at 760° C. and 30 MPa for 60 minutes, so that a thermoelectric conversion element 1 was obtained. An X-ray diffraction confirmed that the thermoelectric conversion element 1 comprised only the clathrate phase.

The Seebeck coefficient was measured by:

cutting a test piece from the thermoelectric conversion element 1;

attaching thermocouple wires to the test piece;

putting the test piece in a heating furnace;

heating the test piece in the heating furnace in such a manner that a temperature difference within the test piece arises; and

measuring the thermal electromotive force generated by the uneven heating.

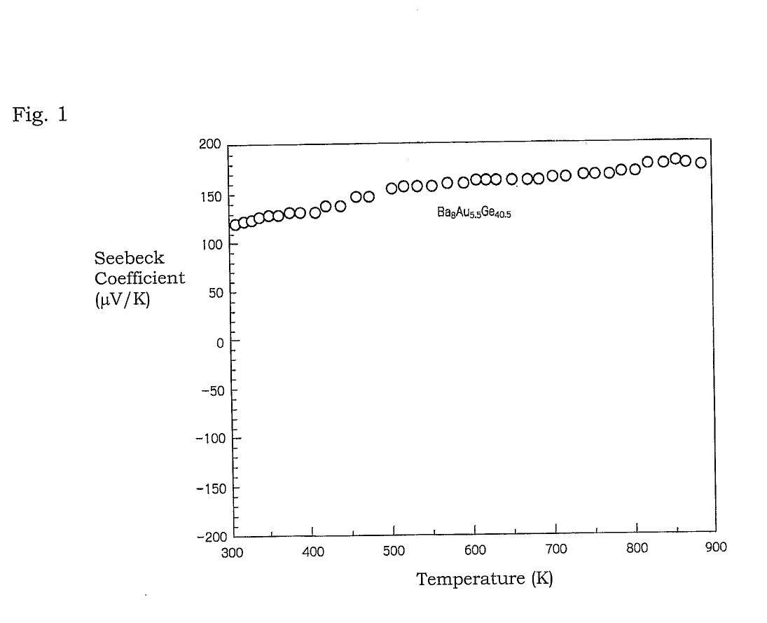

The results are shown in FIG. 1. The results indicated that the thermoelectric conversion element 1 was a p-type thermoelectric semiconductor.

### Example 2

### Preparation of Thermoelectric Conversion Element 2 (Ba₈Au₅Ga₁Ge₄₀)

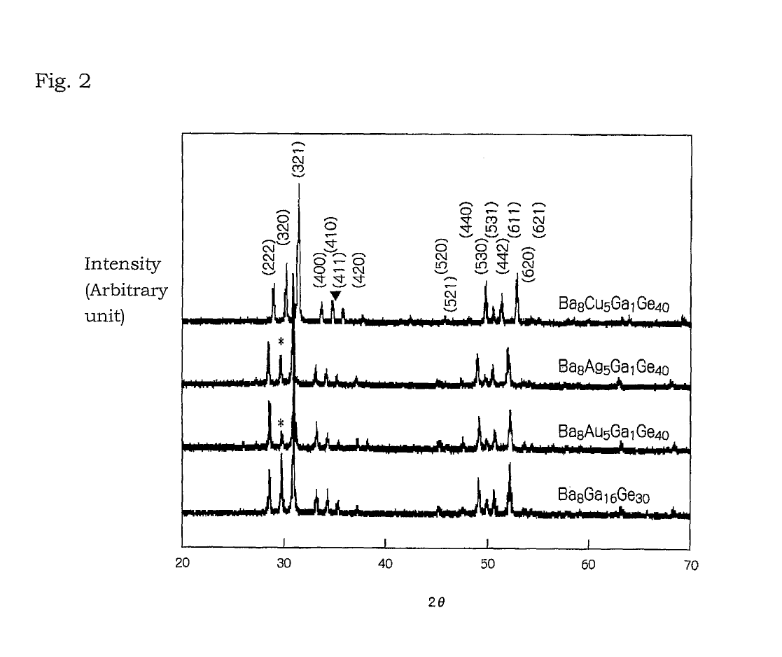

Ba (99.9%), Au (99.99%), Ga (99.9999%), and Ge (99.99%) were used as raw materials. 4.9961 g of Ba, 4.4787 g of Au, 0.3171 g of Ga, and 13.2082 g of Ge were mixed so that the molar ratio of Ba:Au:Ga:Ge was 8:5:1:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Au₅Ga₁Ge₄₀ was synthesized. Then, the synthesized substance Ba₈Au₅Ga₁Ge₄₀ was pulverized with a mortar into particles having a particle size of 75 μm or smaller. The particles of Ba₈Au₅Ga₁Ge₄₀ were sintered by a discharge plasma sintering device at 790° C. and 30 MPa for 1 hour, so that a thermoelectric conversion element 2 was obtained. An X-ray diffraction confirmed that the thermoelectric conversion element 2 comprised only the clathrate phase. The result of the X-ray diffraction is shown in FIG. 2.

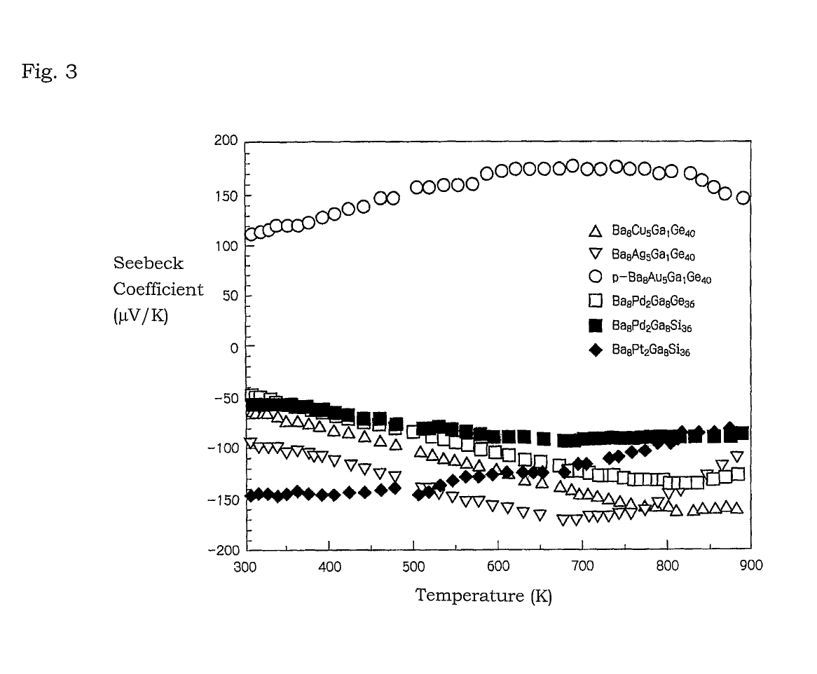

The Seebeck coefficient was measured in the same manner as in Example 1. The results are shown in FIG. 3.

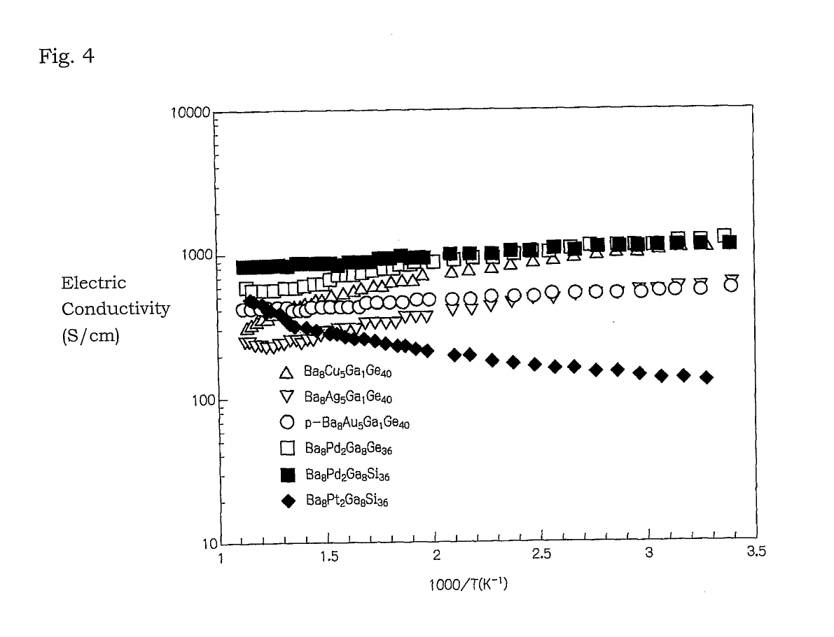

The electric conductivity was measured by the 4-terminal method. The results are shown in FIG. 4.

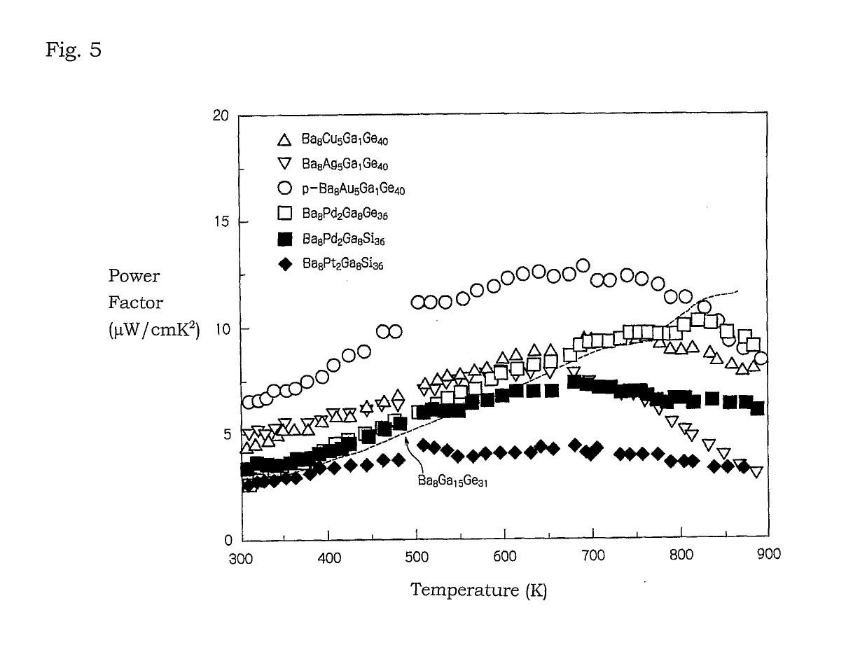

The power factor was calculated from the Seebeck coefficient (α) and electric conductivity (σ). The results are shown in FIG. 5.

From these results, it was confirmed that the thermoelectric conversion element 2 was a material having high thermoelectric characteristics.

### Example 3

### Preparation of Thermoelectric Conversion Element 3 (Ba₈Au₄Ga₄Ge₃₈)

Ba (99.9%), Au (99.9%), Ga (99.9%), and Ge (99.9%) were used as raw materials. 5.1319 g of Ba, 3.6802 g of Au, 1.3027 g of Ga, and 12.8851 g of Ge were mixed so that the molar ratio of Ba:Au:Ga:Ge was 8:4:4:38. Therefore, the total weight was about 23 g. The mixture was melted by being subjected to an arc melting wherein the arc temperature was 1200° C. and the arc melting time was 20 minutes. Thereafter, the mixture was cooled so that Ba₈Au₄Ga₄Ge₃₈ was synthesized. Then, the synthesized substance Ba₈Au₄Ga₄Ge₃₈ was pulverized with a mortar into particles having a particle size of 75 μm or smaller. The particles of Ba₈Au₄Ga₄Ge₃₈ were sintered by a discharge plasma sintering device at 805° C. and 30 MPa for 60 minutes, so that a thermoelectric conversion element 3 was obtained. An X-ray diffraction confirmed that the thermoelectric conversion element 3 comprised only the clathrate phase.

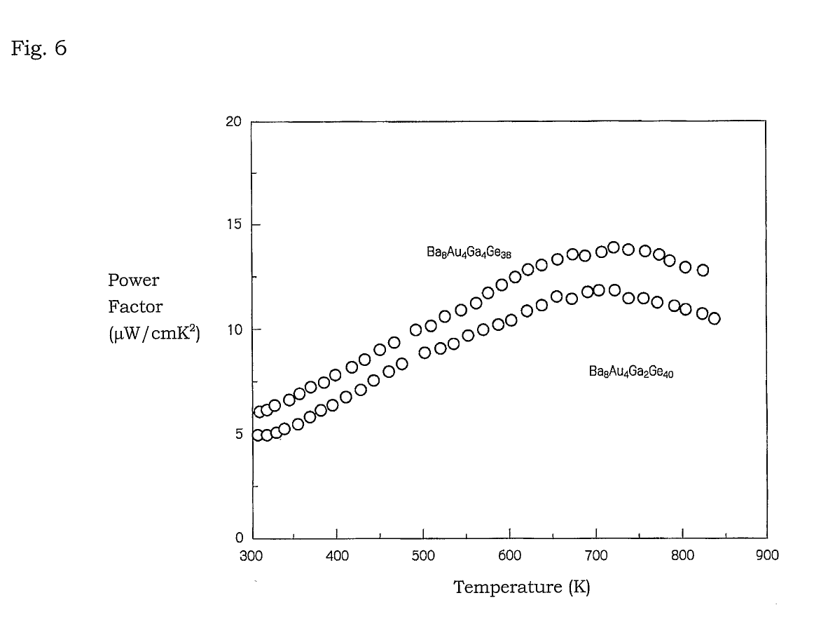

The power factor was calculated in the same manner as in Example 2. The results are shown in FIG. 6. The results confirmed that the thermoelectric conversion element 3 was a material having high thermoelectric characteristics.

### Example 4

### Preparation of Thermoelectric Conversion Element 4 (Ba₈Au₄Ga₂Ge₄₀)

Ba (99.9%), Au (99.9%), Ga (99.9%), and Ge (99.9%) were used as raw materials. 5.1260 g of Ba, 3.6760 g of Au, 0.6506 g of Ga, and 13.5475 g of Ge were mixed so that the molar ratio of Ba:Au:Ga:Ge was 8:4:2:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Au₄Ga₂Ge₄₀ was synthesized. Then, the synthesized substance Ba₈Au₄Ga₂Ge₄₀ was pulverized with a mortar into particles having a particle size of 75 μm or smaller. The particles of Ba₈Au₄Ga₂Ge₄₀ were sintered by a discharge plasma sintering device at 805° C. and 30 MPa for 60 minutes, so that a thermoelectric conversion element 4 was obtained. An X-ray diffraction confirmed that the thermoelectric conversion element 4 comprised only the clathrate phase.

The power factor was calculated in the same manner as in Example 2. The results are shown in FIG. 6. The results confirmed that the thermoelectric conversion element 4 was a material having high thermoelectric characteristics.

### Example 5

### Preparation of Thermoelectric Conversion Element 5 (Ba₈Pt₅Ge₄₁)

Ba (99.9%), Pt (99.9%), and Ge (99.9%) were used as raw materials. 5.0035 g of Ba, 4.4422 g of Pt, and 13.5543 g of Ge were mixed so that the molar ratio of Ba:Pt:Ge was 8:5:41. Therefore, the total weight was about 23 g. The mixture was melted by being subjected to an arc melting wherein the arc temperature was 1200° C. and the arc melting time was 20 minutes. Thereafter, the mixture was cooled so that Ba₈Pt₅Ge₄₁ was synthesized. Then, the synthesized substance Ba₈Pt₅Ge₄₁ was pulverized with a mortar into particles having a particle size of 75 μm or smaller. The particles of Ba₈Pt₅Ge₄₁ were sintered by a discharge plasma sintering device at 780° C. and 30 MPa for 60 minutes, so that a thermoelectric conversion element 5 was obtained. An X-ray diffraction confirmed that the thermoelectric conversion element 5 comprised only the clathrate phase.

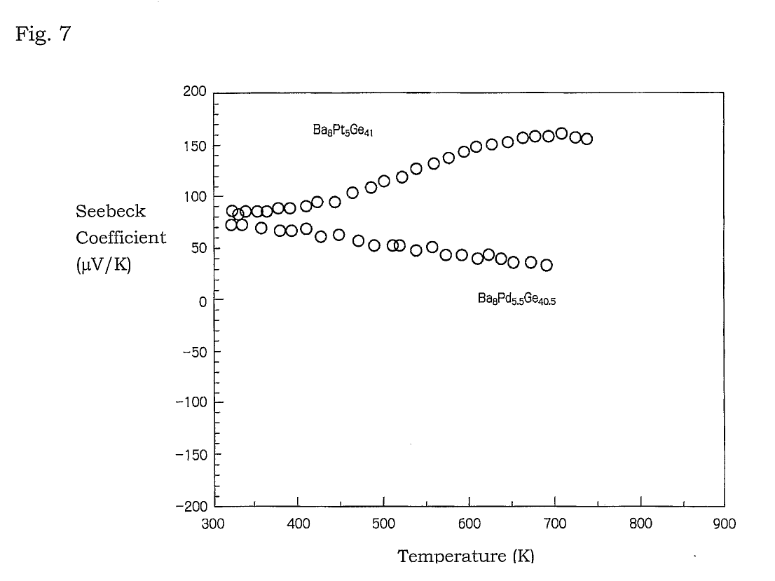

The Seebeck coefficient was measured in the same manner as in Example 1. The results are shown in FIG. 7. The results indicated that the thermoelectric conversion element 5 was a p-type thermoelectric semiconductor.

### Example 6

### Preparation of Thermoelectric Conversion Element 6 (Ba₈Pd_{5.5}Ge_{40.5})

Ba (99.9%), Pd (99.9%), and Ge (99.9%) were used as raw materials. 5.4649 g of Ba, 2.9115 g of Pd, and 14.6237 g of Ge were mixed so that the molar ratio of Ba:Pd:Ge was 8:5.5:40.5. Therefore, the total weight was about 23 g. The mixture was melted by being subjected to an arc melting wherein the arc temperature was 1200° C. and the arc melting time was 20 minutes. Thereafter, the mixture was cooled so that Ba₈Pd_{5.5}Ge_{40.5} was synthesized. Then, the synthesized substance Ba₈Pd_{5.5}Ge_{40.5} was pulverized with a mortar into particles having a particle size of 75 μm or smaller. The particles of Ba₈Pd_{5.5}Ge_{40.5} were sintered by a discharge plasma sintering device at 750° C. and 30 MPa for 60 minutes, so that a thermoelectric conversion element 6 was obtained. An X-ray diffraction confirmed that the thermoelectric conversion element 6 comprised only the clathrate phase.

The Seebeck coefficient was measured in the same manner as in Example 1. The results are shown in FIG. 7. The results indicated that the thermoelectric conversion element 6 was a p-type thermoelectric semiconductor.

### Example 7

### Preparation of Thermoelectric Conversion Element 7 (Ba₈Pd₂Ga₈Ge₃₆)

Ba (99.9%), Pd (99.9%), Ga (99.9999%), and Ge (99.99%) were used as raw materials. 5.6362 g of Ba, 1.0919 g of Pd, 2.8616 g of Ga, and 13.4103 g of Ge were mixed so that the molar ratio of Ba:Pd:Ga:Ge was 8:2:8:36. Therefore, the total weight was about 23 g. The mixture was melted by being subjected to an arc melting wherein the arc temperature was 1200° C. and the arc melting time was 20 minutes. Thereafter, the mixture was cooled so that Ba₈Pd₂Ga₈Ge₃₆ was synthesized. Then, the synthesized substance Ba₈Pd₂Ga₈Ge₃₆ was pulverized with a mortar into particles having a particle size of 75 μm or smaller. The particles of Ba₈Pd₂Ga₈Ge₃₆ were sintered by a discharge plasma sintering device at 775° C. and 30 MPa for 60 minutes, so that a thermoelectric conversion element 7 was obtained. An X-ray diffraction confirmed that the thermoelectric conversion element 7 comprised only the clathrate phase.

The Seebeck coefficient, electric conductivity, and power factor were measured in the same manner as in Example 2. The results are shown in FIGS. 3, 4, and 5, respectively. The results indicated that the thermoelectric conversion element 7 was a material having high thermoelectric characteristics.

### Example 8

### Preparation of Thermoelectric Conversion Element 8 (Ba₈Pd₂Ga₈Si₃₆)

Ba (99.9%), Pd (99.9%), Ga (99.9999%), and Si (99.999%) were used as raw materials. 8.7727 g of Ba, 1.6996 g of Pd, 4.4540 g of Ga, and 8.0737 g of Si were mixed so that the molar ratio of Ba:Pd:Ga:Si was 8:2:8:36. Therefore, the total weight was about 23 g. The mixture was melted by being subjected to an arc melting wherein the arc temperature was 1300° C. and the arc melting time was 20 minutes. Thereafter, the mixture was cooled so that Ba₈Pd₂Ga₈Si₃₆ was synthesized. Then, the synthesized substance Ba₈Pd₂Ga₈Si₃₆ was pulverized with a mortar into particles having a particle size of 75 μm or smaller. The particles of Ba₈Pd₂Ga₈Si₃₆ were sintered by a discharge plasma sintering device at 745° C. and 30 MPa for 60 minutes, so that a thermoelectric conversion element 8 was obtained. An X-ray diffraction confirmed that the thermoelectric conversion element 8 comprised only the clathrate phase.

The Seebeck coefficient, electric conductivity, and power factor were measured in the same manner as in Example 2. The results are shown in FIGS. 3, 4, and 5, respectively. The results indicated that the thermoelectric conversion element 8 was a material having high thermoelectric characteristics.

### Example 9

### Preparation of Thermoelectric Conversion Element 9 (Ba₈Pt₂Ga₈Si₃₆)

Ba (99.9%), Pt (99.9%), Ga (99.9999%), and Si (99.999%) were used as raw materials. 8.2640 g of Ba, 2.9348 g of Pt, 4.1957 g of Ga, and 7.6055 g of Si were mixed so that the molar ratio of Ba:Pt:Ga:Si was 8:2:8:36. Therefore, the total weight was about 23 g. The mixture was melted by being subjected to an arc melting wherein the arc temperature was 1300° C. and the arc melting time was 20 minutes. Thereafter, the mixture was cooled so that Ba₈Pt₂Ga₈Si₃₆ was synthesized. Then, the synthesized substance Ba₈Pt₂Ga₈Si₃₆ was pulverized with a mortar into particles having a particle size of 75 μm or smaller. The particles of Ba₈Pt₂Ga₈Si₃₆ were sintered by a discharge plasma sintering device at 890° C. and 30 MPa for 60 minutes, so that a thermoelectric conversion element 9 was obtained. An X-ray diffraction confirmed that the thermoelectric conversion element 9 comprised only the clathrate phase.

The Seebeck coefficient, electric conductivity, and power factor were measured in the same manner as in Example 2. The results are shown in FIGS. 3, 4, and 5, respectively. The results indicated that the thermoelectric conversion element 9 was a material having high thermoelectric characteristics.

### Example 10

### Preparation of Thermoelectric Conversion Element 10 (Ba₈Cu_{5.5}Ga_{0.5}Ge₄₀)

Ba (99.9%), Cu (99.9%), Ga (99.9%), and Ge (99.9%) were used as raw materials. 5.7604 g of Ba, 1.8326 g of Cu, 0.1828 g of Ga, and 15.2242 g of Ge were mixed so that the molar ratio of Ba:Cu:Ga:Ge was 8:5.5:0.5:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Cu_{5.5}Ga_{0.5}Ge₄₀ was synthesized. Then, the synthesized substance Ba₈Cu_{5.5}Ga_{0.5}Ge₄₀ was pulverized with a mortar into particles having a particle size of 75 μm or smaller. The particles of Ba₈Cu_{5.5}Ga_{0.5}Ge₄₀ were sintered by a discharge plasma sintering device at 810° C. and 30 MPa for 60 minutes, so that a thermoelectric conversion element 10 was obtained. An X-ray diffraction confirmed that the thermoelectric conversion element 10 comprised only the clathrate phase.

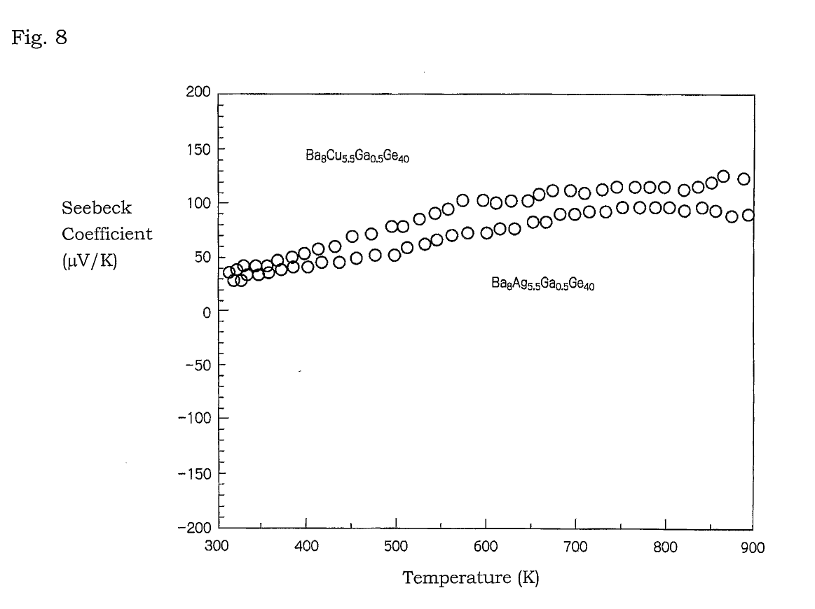

The Seebeck coefficient was measured in the same manner as in Example 1. The results are shown in FIG. 8. The results indicated that the thermoelectric conversion element 10 was a p-type thermoelectric semiconductor.

### Example 11

### Preparation of Thermoelectric Conversion Element 11 (Ba₈Ag_{5.5}Ga_{0.5}Ge₄₀)

Ba (99.9%), Ag (99.9%), Ga (99.9%), and Ge (99.9%) were used as raw materials. 7.1180 g of Ba, 3.8438 g of Ag, 0.2259 g of Ga, and 18.8123 g of Ge were mixed so that the molar ratio of Ba:Ag:Ga:Ge was 8:5.5:0.5:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Ag_{5.5}Ga_{0.5}Ge₄₀ was synthesized. Then, the synthesized substance Ba₈Ag_{5.5}Ga_{0.5}Ge₄₀ was pulverized with a mortar into particles having a particle size of 75 μm or smaller. The particles of Ba₈Ag_{5.5}Ga_{0.5}Ge₄₀ were sintered by a discharge plasma sintering device at 780° C. and 30 MPa for 40 minutes, so that a thermoelectric conversion element 11 was obtained. An X-ray diffraction confirmed that the thermoelectric conversion element 11 comprised only the clathrate phase.

The Seebeck coefficient was measured in the same manner as in Example 1. The results are shown in FIG. 8. The results indicated that the thermoelectric conversion element 11 was a p-type thermoelectric semiconductor.

### Example 12

### Preparation of Thermoelectric Conversion Element 12 (Ba₈Cu₅Ga₁Ge₄₀)

Ba (99.9%), Cu (99.99%), Ga (99.9999%), and Ge (99.99%) were used as raw materials. 5.7552 g of Ba, 1.6645 g of Cu, 0.3653 g of Ga, and 15.2150 g of Ge were mixed so that the molar ratio of Ba:Cu:Ga:Ge was 8:5:1:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Cu₅Ga₁Ge₄₀ was synthesized. Then, the synthesized substance Ba₈Cu₅Ga₁Ge₄₀ was pulverized with a mortar into particles having a particle size of 75 μm or smaller. The particles of Ba₈Cu₅Ga₁Ge₄₀ were sintered by a discharge plasma sintering device at 815° C. and 30 MPa for 60 minutes, so that a thermoelectric conversion element 12 was obtained. An X-ray diffraction confirmed that the thermoelectric conversion element 12 comprised only the clathrate phase. The result of the X-ray diffraction is shown in FIG. 2.

The Seebeck coefficient, electric conductivity, and power factor were measured in the same manner as in Example 2. The results are shown in FIGS. 3, 4, and 5, respectively. The results indicated that the thermoelectric conversion element 12 was a material having high thermoelectric characteristics.

### Example 13

### Preparation of Thermoelectric Conversion Element 13 (Ba₈Ag₅Ga₁Ge₄₀)

Ba (99.9%), Ag (99.99%), Ga (99.9999%), and Ge (99.99%) were used as raw materials. 5.4787 g of Ba, 2.6896 g of Ag, 0.3477 g of Ga, and 14.4840 g of Ge were mixed so that the molar ratio of Ba:Ag:Ga:Ge was 8:5:1:40. Therefore, the total weight was about 23 g. The mixture was melted by being subjected to an arc melting wherein the arc temperature was 1200° C. and the arc melting time was 20 minutes. Thereafter, the mixture was cooled so that Ba₈Ag₅Ga₁Ge₄₀ was synthesized. Then, the synthesized substance Ba₈Ag₅Ga₁Ge₄₀ was pulverized with a mortar into particles having a particle size of 75 μm or smaller. The particles of Ba₈Ag₅Ga₁Ge₄₀ were sintered by a discharge plasma sintering device at 785° C. and 30 MPa for 60 minutes, so that a thermoelectric conversion element 13 was obtained. An X-ray diffraction confirmed that the thermoelectric conversion element 13 comprised only the clathrate phase. The result of the X-ray diffraction is shown in FIG. 2.

The Seebeck coefficient, electric conductivity, and power factor were measured in the same manner as in Example 2. The results are shown in FIGS. 3, 4, and 5, respectively. The results indicated that the thermoelectric conversion element 13 was a material having high thermoelectric characteristics.

### Example 14

### Preparation of Thermoelectric Conversion Element 14 (Ba₈Cu₄Ga₄Ge₃₈)

Ba (99.9%), Cu (99.9%), Ga (99.9%), and Ge (99.9%) were used as raw materials. 5.7558 g of Ba, 1.3317 g of Cu, 1.4610 g of Ga, and 14.4517 g of Ge were mixed so that the molar ratio of Ba:Cu:Ga:Ge was 8:4:4:38. Therefore, the total weight was about 23 g. The mixture was melted by being subjected to an arc melting wherein the arc temperature was 1200° C. and the arc melting time was 20 minutes. Thereafter, the mixture was cooled so that Ba₈Cu₄Ga₄Ge₃₈ was synthesized. Then, the synthesized substance Ba₈Cu₄Ga₄Ge₃₈ was pulverized with a mortar into particles having a particle size of 75 μm or smaller. The particles of Ba₈Cu₄Ga₄Ge₃₈ were sintered by a discharge plasma sintering device at 830° C. and 30 MPa for 60 minutes, so that a thermoelectric conversion element 14 was obtained. An X-ray diffraction confirmed that the thermoelectric conversion element 14 comprised only the clathrate phase.

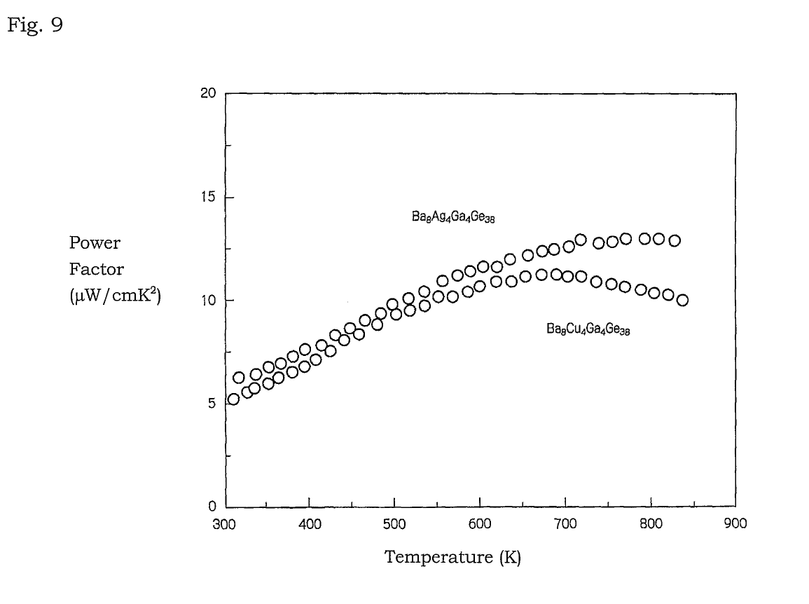

The power factor was measured in the same manner as in Example 2. The results are shown in FIG. 9. The results indicated that the thermoelectric conversion element 14 was a material having high thermoelectric characteristics.

### Example 15

### Preparation of Thermoelectric Conversion Element 15 (Ba₈Ag₄Ga₄Ge₃₈)

Ba (99.9%), Ag (99.9%), Ga (99.9%), and Ge (99.99%) were used as raw materials. 5.5324 g of Ba, 2.1727 g of Ag, 1.4044 g of Ga, and 13.8905 g of Ge were mixed so that the molar ratio of Ba:Ag:Ga:Ge was 8:4:4:38. Therefore, the total weight was about 23 g. The mixture was melted by being subjected to an arc melting wherein the arc temperature was 1200° C. and the arc melting time was 20 minutes. Thereafter, the mixture was cooled so that Ba₈Ag₄Ga₄Ge₃₈ was synthesized. Then, the synthesized substance Ba₈Ag₄Ga₄Ge₃₈ was pulverized with a mortar into particles having a particle size of 75 μm or smaller. The particles of Ba₈Ag₄Ga₄Ge₃₈ were sintered by a discharge plasma sintering device at 800° C. and 30 MPa for 60 minutes, so that a thermoelectric conversion element 15 was obtained. An X-ray diffraction confirmed that the thermoelectric conversion element 15 comprised only the clathrate phase.

The power factor was measured in the same manner as in Example 2. The results are shown in FIG. 9. The results indicated that the thermoelectric conversion element 15 was a material having high thermoelectric characteristics.

### Example 16

### Preparation of Thermoelectric Conversion Element 16 (Ba₈Ga₁₆Ge₃₀) (with Heat-Treatment)

Ba (99.9%), Ga (99.9999%), and Ge (99.99%) were used as raw materials. 5.8598 g of Ba, 5.8051 g of Ga, and 11.3352 g of Ge were mixed so that the molar ratio of Ba:Ga:Ge was 8:16:30. Therefore, the total weight was about 23 g. The mixture was melted by being subjected to an arc melting wherein the arc temperature was 1200° C. and the arc melting time was 20 minutes. Thereafter, the mixture was cooled so that Ba₈Ga₁₆Ge₃₀ was synthesized.

Then, the synthesized Ba₈Ga₁₆Ge₃₀ was heat-treated at 750° C. for 120 hours. Then, the synthesized substance Ba₈Ga₁₆Ge₃₀ was pulverized with a mortar into particles having a particle size of 75 μm or smaller. The particles of Ba₈Ga₁₆Ge₃₀ were sintered by a discharge plasma sintering device at 790° C. and 30 MPa for 1.5 hours, so that a thermoelectric conversion element 16 was obtained. An X-ray diffraction confirmed that the thermoelectric conversion element 16 comprised only the clathrate phase. The result of the X-ray diffraction is shown in FIG. 2.

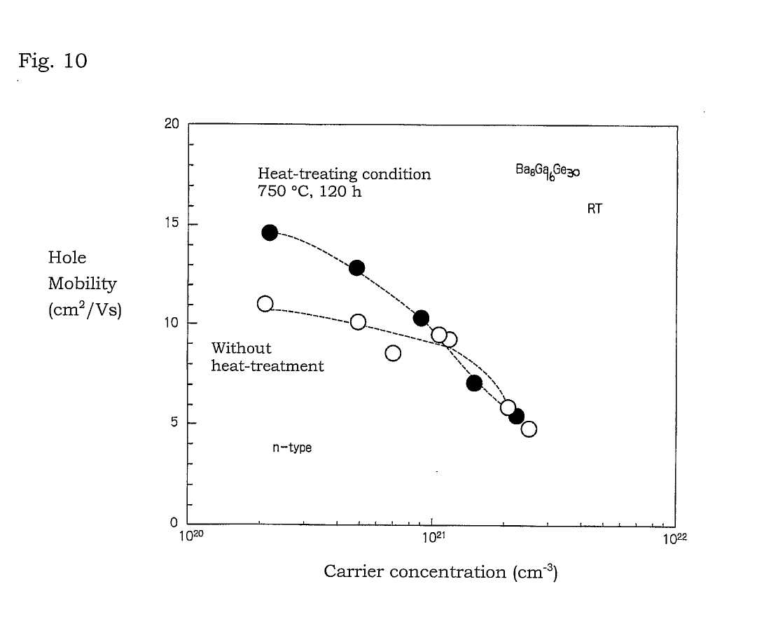

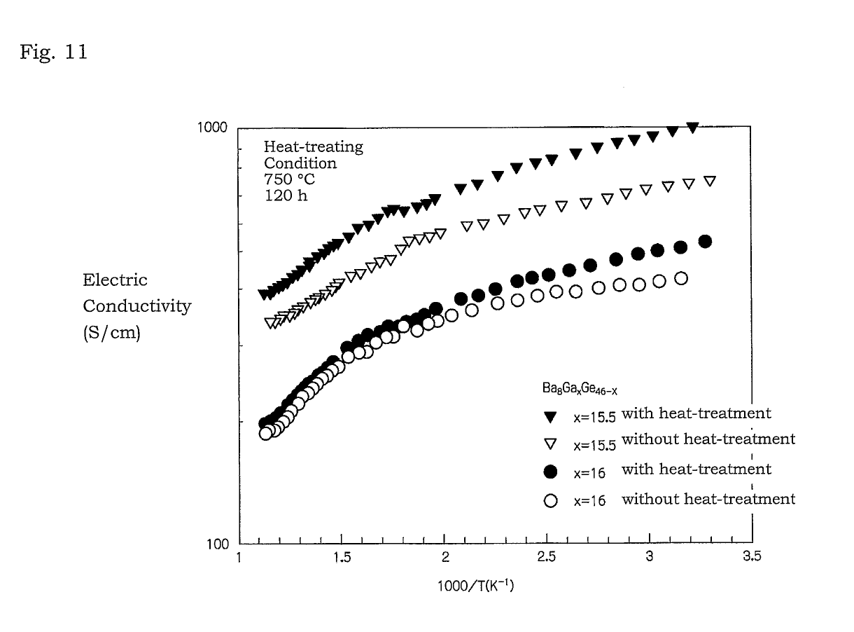

The carrier concentration and hole mobility of the thermoelectric conversion element 16 were measured by the Van der Pauw method. Specifically, the voltage was measured while changing the electric current through the sample to 3 mA, then to 5 mA, then to 10 mA. The electric current-voltage characteristic was plotted on a graph and the voltage component which was proportional to the electric current was considered as the true value and used in the calculation. In the measurement, the applied magnetic field was 1 T and the temperature was 27±5° C. The results are shown in FIG. 10. Also, the electric conductivity was measured in the same manner as in Example 2. The results were shown in FIG. 11.

### Comparative Example 1

### Production of Thermoelectric Conversion Element 17 (Ba₈Ga₁₆Ge₃₀) (without Heat-Treatment)

A thermoelectric conversion element 17 was prepared in the same manner as in Example 16 except that the synthesized Ba₈Ga₁₆Ge₃₀ was not subjected to the heat-treatment. The carrier concentration and hole mobility were measured in the same manner as in Example 16, and the electric conductivity was measured in the same manner as in Example 2. The results are shown in FIGS. 10 and 11.

### Example 17

### Preparation of Thermoelectric Conversion Element 18 (Ba₈Ga_{15.5}Ge_{30.5}) (with Heat-Treatment)

Ba (99.9%), Ga (99.9999%), and Ge (99.99%) were used as raw materials. 5.8579 g of Ba, 5.6218 g of Ga, and 11.5203 g of Ge were mixed so that the molar ratio of Ba:Ga:Ge was 8:15.5:30.5. Therefore, the total weight was about 23 g. The mixture was melted by being subjected to an arc melting wherein the arc temperature was 1200° C. and the arc melting time was 20 minutes. Thereafter, the mixture was cooled so that Ba₈Ga_{15.5}Ge_{30.5} was synthesized.

Then, the synthesized Ba₈Ga_{15.5}Ge_{30.5} was heat-treated at 750° C. for 120 hours. Then, the synthesized substance Ba₈Ga_{15.5}Ge_{30.5} was pulverized with a mortar into particles having a particle size of 75 μm or smaller. The particles of Ba₈Ga_{15.5}Ge_{30.5} were sintered by a discharge plasma sintering device at 810° C. and 30 MPa for 1 hour, so that a thermoelectric conversion element 18 was obtained. An X-ray diffraction confirmed that the thermoelectric conversion element 18 comprised only the clathrate phase. The electric conductivity was measured in the same manner as in Example 2. The results are shown in FIG. 11.

### Comparative Example 2

### Production of Thermoelectric Conversion Element 19 (Ba₈Ga_{15.5}Ge_{30.5}) (without Heat-Treatment)

A thermoelectric conversion element 19 was prepared in the same manner as in Example 17 except that the synthesized Ba₈Ga_{15.5}Ge_{30.5} was not subjected to the heat-treatment. The electric conductivity was measured in the same manner as in Example 2. The results are shown in FIG. 11.

As is clear from the FIGS. 10 and 11, the heat-treatment improves the thermoelectric conversion efficiency of the thermoelectric conversion element.

As described above, according to the invention, it is possible to provide novel clathrate compounds having p-type semiconductor characteristics and to provide novel clathrate compounds showing thermoelectric characteristics. The invention also provides thermoelectric conversion elements comprising the clathrate compounds of the inventions. The invention further provides a method for producing thermoelectric conversion elements by which the thermoelectric conversion efficiency of the thermoelectric conversion elements comprising sintered bodies of the clathrate compounds whose constituent atoms include Ba and Ge can be improved.

1. A clathrate compound represented by the following composition formula (1):
Ba₈AuₐGe₄₆₋ₐ(16/3≦a≦6) Composition formula (1).

2. A clathrate compound represented by the following composition formula (2):
Ba₈Au_{b}Ga_{c}Ge_{46-b-c}(5≦b<16/3,c=16−3b) Composition formula (2).

3. A clathrate compound represented by the following composition formula (3):
Ba₈Au_{d}GaₑGe_{46-d-e}(0≦d<5,e=16−3d) Composition formula (3).

4. A clathrate compound represented by the following composition formula (4):
Ba₈Au_{f}Ga_{6-f}Ge₄₀(0<f<6) Composition formula (4).

5. A clathrate compound represented by the following composition formula (5):
Ba₈Pt_{g}Ge_{46-g}(4<g<6) Composition formula (5).

6. A clathrate compound represented by the following composition formula (6):
Ba₈PdₕGe₄₆₋ₕ(5<h<6) Composition formula (6).

7. A clathrate compound represented by the following composition formula (7):
Ba₈PdᵢGaⱼGe₄₆₋ᵢ₋ⱼ(0≦i≦4,j=16−4i) Composition formula (7).

8. A clathrate compound represented by the following composition formula (8):
Ba₈AₖGa₁Si₄₆₋ₖ₋₁(0≦k≦4,l=16−4k) Composition formula (8)
wherein A in Composition formula (8) represents Pd or Pt.

9. A clathrate compound represented by the following composition formula (9):
Ba₈EₘGa₆₋ₘGe₄₀(5<m<6) Composition formula (9)
wherein E in Composition formula (9) represents Cu or Ag.

10. A clathrate compound represented by the following composition formula (10):
Ba₈GₙGa₆₋ₙGe₄₀(0<n≦5) Composition formula (10)
wherein G in Composition formula (10) represents Cu or Ag.

11. A clathrate compound represented by the following composition formula (11):
Ba₈J₀GaₚGe₄₆₋ₒ₋ₚ(0≦o≦16/3,p=16−3o) Composition formula (11)
wherein J in Composition formula (11) represents Cu or Ag.

12. A thermoelectric conversion element comprising a sintered body of the clathrate compound of claim 1.

13. A thermoelectric conversion element comprising a sintered body of the clathrate compound of claim 2.

14. A thermoelectric conversion element comprising a sintered body of the clathrate compound of claim 3.

15. A thermoelectric conversion element comprising a sintered body of the clathrate compound of claim 4.

16. A thermoelectric conversion element comprising a sintered body of the clathrate compound of claim 5.

17. A thermoelectric conversion element comprising a sintered body of the clathrate compound of claim 6.

18. A thermoelectric conversion element comprising a sintered body of the clathrate compound of claim 7.

19. A thermoelectric conversion element comprising a sintered body of the clathrate compound of claim 8.

20. A thermoelectric conversion element comprising a sintered body of the clathrate compound of claim 9.

21. A thermoelectric conversion element comprising a sintered body of the clathrate compound of claim 10.

22. A thermoelectric conversion element comprising a sintered body of the clathrate compound of claim 11.

23. A method for producing a thermoelectric conversion element comprising a sintered body of a clathrate compound whose constituent atoms include Ba and Ge, the method comprising:
melting elements which are to constitute the clathrate compound so as to synthesize the clathrate compound;
heat-treating the synthesized clathrate compound at 650 to 900° C. for 50 to 250 hours;
forming particles from the heat-treated clathrate compound; and
sintering the particles.
